(19) United States
(12) Patent Application Publication
(10) Pub. No.: US 2016/0358786 A1
(43) Pub. Date: Dec. 8, 2016

(54) Techniques for Spin-on-Carbon Planarization

(71) Applicant: Tokyo Electron Limited, Tokyo (JP)

(72) Inventors: Joshua S. Hooge, Austin, TX (US); Benjamen M. Rathsack, Austin, TX (US); Michael A. Carcasi, Austin, TX (US); Mark H. Somervell, Austin, TX (US); Ian J. Brown, Austin, TX (US); Wallace P. Printz, Austin, TX (US)

(21) Appl. No.: 15/171,188

(22) Filed: Jun. 2, 2016

Related U.S. Application Data
(60) Provisional application No. 62/170,024, filed on Jun. 2, 2015.

(51) Int. Cl. H01L 21/3105; H01L 21/027; H01L 21/02; H01L 21/311; H01L 21/67; H01L 21/68

(52) U.S. Cl. CPC H01L 21/31051; H01L 21/67115; H01L 21/68; H01L 21/02115; H01L 21/02282; H01L 21/31133; H01L 21/0274

(57) ABSTRACT

Systems and methods for SOC planarization are described. In an embodiment, an apparatus for SOC planarization includes a substrate holder configured to support a microelectronic substrate. Additionally, the apparatus may include a light source configured to emit ultraviolet (UV) light toward a surface of the microelectronic substrate. In an embodiment, the apparatus may also include an isolation window disposed between the light source and the microelectronic substrate. Also, the apparatus may include a gas distribution unit configured to inject gas in a region between the isolation window and the microelectronic substrate. Furthermore, the apparatus may include an etchback leveling component configured to reduce non-uniformity of a UV light treatment of the microelectronic substrate.

### BACKGROUND OF THE INVENTION

Field of Invention

The present invention relates to systems and methods for substrate processing, and more particularly to systems and methods for spin-on-carbon (SOC) planarization.

Description of Related Art

Disclosed herein are methods and apparatuses related to semiconductor patterning using spin-on-carbon (SOC) materials. In order to achieve high aspect ratio patterns it is common to use a multilayer stack. The photoresist is kept thin to minimize pattern collapse and patterned into a thin silicon containing layer. That pattern is transferred into a thick carbon layer to produce high aspect ratio features which can then be etched into the underlying silicon. Spin-on-carbon is cheaper and planarizes the surface better than chemical vapor deposition (CVD) carbon. However as process margins continue to decrease with the development of smaller computer chips, the planarization of the carbon needs to improve further.

One approach to planarize SOC materials using an ultraviolet (UV) etchback process is shown in FIGS. 1A-1C. As shown in FIG. 1A, one or more features 104 may be formed on a surface of a substrate 102, and a first SOC layer 106 may be formed over the substrate 102. As shown, there is significant non-uniformity 108 in the surface of the first SOC layer 106. FIG. 1B illustrates the device after a UV etchback process has been performed. As illustrated, the etchback process removes a portion of the first SOC layer 106. FIG. 1C illustrates the device after a second SOC layer 110 is applied. As shown, the non-uniformity 112 of the second SOC layer 110 may be smaller than the non-uniformity 108 of the first SOC layer 106. One of ordinary skill will recognize that the steps of such a process may be performed in various alternative sequences. For example, the second SOC layer may be disposed on the first SOC layer 106 prior to etchback, which may limit exposure of underlying features.

Systems used to perform the UV etchback process for planarization often include one or more UV light sources and a window for allowing UV light to enter a chamber that holds a workpiece, such as a wafer. Additionally, such systems may include an air or concentrated oxygen source for introducing oxygen to the UV light, and thereby creating ozone and oxygen radicals that aid in the etchback process.

Examples of prior processes and hardware for UV etchback are described in Japan Pat. App. Pub. No. JP 2014-165252, published on Mar. 5, 2015, which is incorporated herein in its entirety. However, the embodiments disclosed herein are not limited to the processes and hardware described in JP 2014-165252. These embodiments may be used more broadly within the context of SOC etch back or planarization. Unfortunately, deficiencies in prior UV etchback systems, such as unequal intensities of UV radiation on the surface of the device, or unequal concentration of ozone and oxygen radicals in the chamber, may create non-uniformity in the UV etchback process.

### SUMMARY OF THE INVENTION

Systems and methods for SOC planarization are described. In an embodiment, an apparatus for SOC planarization includes a substrate holder configured to support a microelectronic substrate. Additionally, the apparatus may include a light source configured to emit ultraviolet (UV) light toward a surface of the microelectronic substrate. In an embodiment, the apparatus may also include an isolation window disposed between the light source and the microelectronic substrate. Also, the apparatus may include a gas distribution unit configured to inject gas in a region between the isolation window and the microelectronic substrate. Furthermore, the apparatus may include an etchback leveling component configured to reduce non-uniformity of a UV light treatment of the microelectronic substrate.

In an embodiment, a method includes receiving a substrate comprising a first layer disposed over a patterned underlying layer, the film comprising a surface with a first non-uniformity. The method may also include exposing the film to a first bake at a first temperature that matches a solubility control region for the film. Additionally, the method may include removing a portion of the film by exposing the film to a liquid solvent. Also, the method may include applying a second coating of the film. In an embodiment, the method also includes exposing the film to a second bake at a second temperature that cures the film, wherein the film comprises a surface with a second non-uniformity being less than the first non-uniformity.

### BRIEF DESCRIPTION OF THE DRAWINGS

The accompanying drawings, which are incorporated in and constitute a part of this specification, illustrate embodiments of the invention and, together with the general description of the invention given above, and the detailed description given below, serve to describe the invention.

FIG. 1A depicts a first stage of an SOC planarization process of the prior art.

FIG. 1B depicts a second stage of an SOC planarization process of the prior art.

FIG. 1C depicts a third stage of an SOC planarization process of the prior art.

FIG. 2 is a schematic diagram illustrating one embodiment of a system for SOC planarization.

FIG. 3A illustrates SOC thickness uniformity results from a UV etchback system without an etchback leveler.

FIG. 3B illustrates SOC thickness uniformity results from a UV etchback system with an embodiment of an etchback leveler.

FIG. 4 illustrates an embodiment of a system for SOC planarization.

FIG. 5 illustrates an embodiment of a system for SOC planarization.

FIG. 6A illustrates an embodiment of a UV light source.

FIG. 6B illustrates an embodiment of a UV light source with a system for SOC planarization.

FIG. 6C illustrates an embodiment of a UV light source with a system for SOC planarization.

FIG. 7A is a side view diagram illustrating one embodiment of a system for SOC planarization.

FIG. 7B is a top view diagram illustrating one embodiment of a system for SOC planarization.

FIG. 8A is a side view diagram illustrating one embodiment of a system for SOC planarization.

FIG. 8B is a top view diagram illustrating one embodiment of a system for SOC planarization.

FIG. 8C is a side view diagram illustrating one embodiment of a system for SOC planarization.

FIG. 8D is a top view diagram illustrating one embodiment of a system for SOC planarization.

FIG. 9 is a side view diagram illustrating one embodiment of a system for SOC planarization.

FIG. 10A is a side view diagram illustrating one embodiment of a system for SOC planarization.

FIG. 10B is a top view diagram illustrating one embodiment of a system for SOC planarization.

FIG. 11A is a process flow diagram illustrating one embodiment of a method for SOC planarization.

FIG. 11B is a diagram illustrating the solubility control region for methods disclosed herein.

FIG. 11C is a diagram illustrating various characteristics for films disclosed herein.

FIG. 12 is a schematic flowchart diagram illustrating one embodiment of a method for SOC planarization.

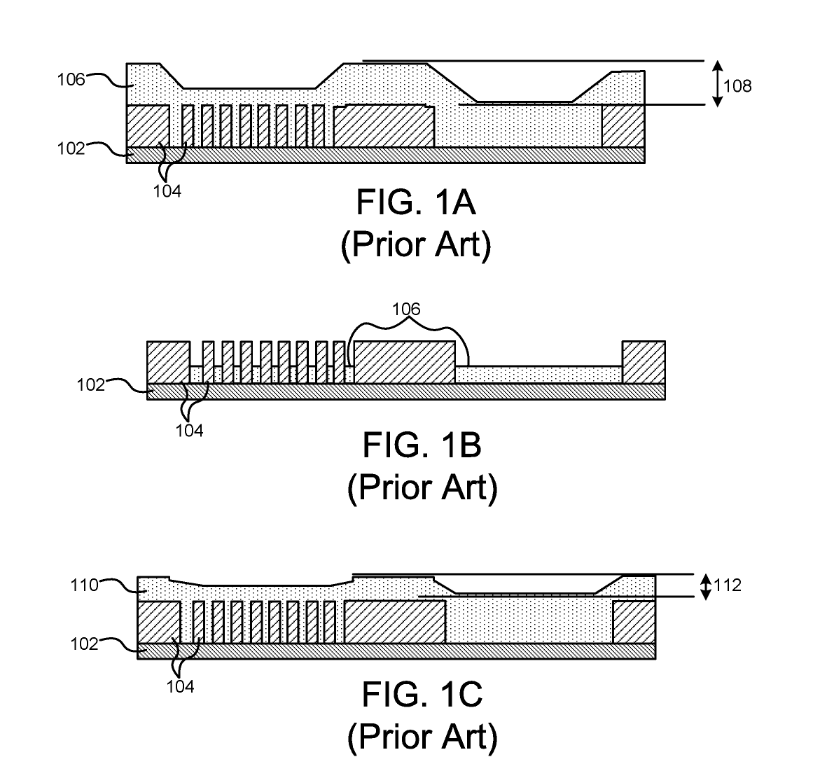

### DETAILED DESCRIPTION OF EMBODIMENTS OF THE INVENTION

Methods and systems for planarization are presented. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale. In referencing the figures, like numerals refer to like parts throughout.

Reference throughout this specification to “one embodiment” or “an embodiment” or variation thereof means that a particular feature, structure, material, or characteristic described in connection with the embodiment is included in at least one embodiment of the invention, but does not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Additionally, it is to be understood that “a” or “an” may mean “one or more” unless explicitly stated otherwise.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

As used herein, the term “substrate” means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The described embodiments are focused on improving the uniformity of the UV irradiation or the uniformity of the reactive oxygen species generated across the wafer. Exposing the entire wafer at one time has throughput advantages but creates a uniformity challenge. One embodiment adds a diffusive layer to the window under the lamp to spread the illumination more evenly. This diffusive layer can be a roughened or patterned surface. Another embodiment uses an absorbing layer on the window with varying composition or thickness to even out the light intensity. Additional embodiments change the thickness of the window to take advantage of the natural absorbance of the window to even out the light intensity.

One embodiment uses an aperture similar to a camera which has an adjustable radius. Combining this aperture with an annular lens can allow a controllable radial intensity. Other embodiments scan the lamp across the wafer surface. A flow of oxygen is directed in the opposite direction of the scanning lamp to ensure that the area of the wafer just beneath the lamp always receives a high oxygen concentration. Alternatively the wafer can be moved under the lamp to accomplish scanning. Also the window and lamp can scan together such that a smaller window can be used to reduce cost. Another embodiment uses a ring of pins on the backside of the wafer to rotate the wafer during exposure. The lamps can be positioned to generate a uniform intensity on a rotating wafer.

The reaction rate of the SOC removal is dependent on the temperature of the wafer. Another embodiment uses a backside IR LED bake to heat the wafer. The different LED panels can be adjusted independently to correct for illumination or oxygen concentration differences which impact the reaction rate across the wafer. Further embodiments use small holes in the window to allow oxygen to be delivered more uniformly across the wafer. Changing the size or orientation of the holes across the wafer can correct for variations in the light intensity across the wafer. Other embodiments generate active oxygen species outside of the chamber and then pumps the gas to the wafer. UV light would still be used the break surface bonds and create ozone but the reaction rate can hastened with the outside introduction of oxygen species. The light source can be a higher wavelength (200-300 nm) since ozone generation would no longer be necessary. A commercial ozone generator or an atomic oxygen beam can be used.

One embodiment uses a low temperature bake and solvent SOC removal in place of UV exposure. The solubility of SOC chemicals is tunable by adjusting the bake temperature after SOC coating. Using a lower temperature bake will allow solvent applied to the wafer to remove the SOC. A final high temperature bake would then render the SOC insoluble during further processing steps.

Still another embodiment incorporates a digital light processing (DLP) system that exposes portions of the SOC to increase the etch back rate at selected locations on the substrate. The DLP system may use an array of reflective components that can be programmed to reflect UV light towards or away from specific locations on the substrate. In this way, the etch back rate can be tuned based on the amount and direction of the UV light. For example, large arrays or features on the substrate may require different amounts of energy to increase or enable uniform SOC removal across the substrate. The DLP system may be used as stand-alone etch back removal technique or may be used in combination with one or more of the techniques disclosed herein. These and other embodiments are described below with reference to various views and figures.

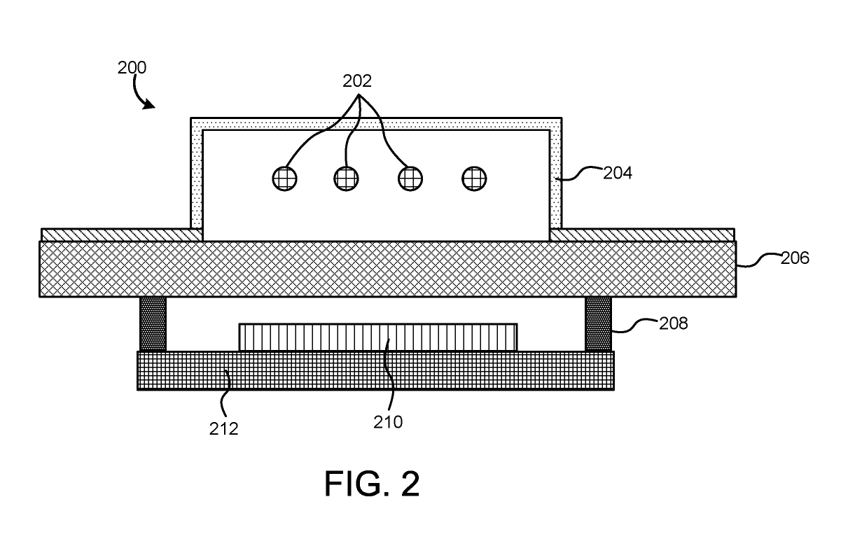

FIG. 2 illustrates an embodiment of a system 200 for SOC planarization, which may be configured according to one or more of the embodiments described herein for enhanced planarization of SOC materials as compared with prior systems. In an embodiment, the system 200 includes one or more UV lamps 202, a window 204, and a heater 212. The window 206 transmits UV light but separates any reactive oxygen species created from the lamp 202. Air or concentrated O₂ is inserted into the gap between the wafer 210 and window 206 where it is converted by UV light into reactive oxygen species such ozone, atomic oxygen, singlet oxygen, triplet oxygen, and oxygen radicals. The UV light also breaks surface bonds to create a more reactive surface. The SOC material then leaves the chamber as CO2. The heater 212 raises the wafer temperature to hasten the reaction rate.

In one embodiment, the hardware uses a UV lamp 202, a window 206, and air flow to remove excess SOC from the wafer surface. Initially the SOC coating over topography in a typical tri-layer flow does not produce a uniform surface. A second SOC coating is performed to planarize the surface. The wafer is then moved into a UV etch module to remove excess SOC. The UV lamp 202 exposes the wafer 210 to break chemical bonds at the surface and energizes oxygen to form active oxygen species such as ozone and atomic oxygen. The combination of the prepared surface and active oxygen causes material to be removed and leave the module as CO₂. A small gap between the wafer 210 and window 206 ensures that exposed oxygen is close to the wafer surface. A preferred embodiment of a UV etch module would have an equivalent removal rate at any point on the wafer surface. It is also advantageous to have the removal rate be as fast as possible to reduce the cost of using multiple modules.

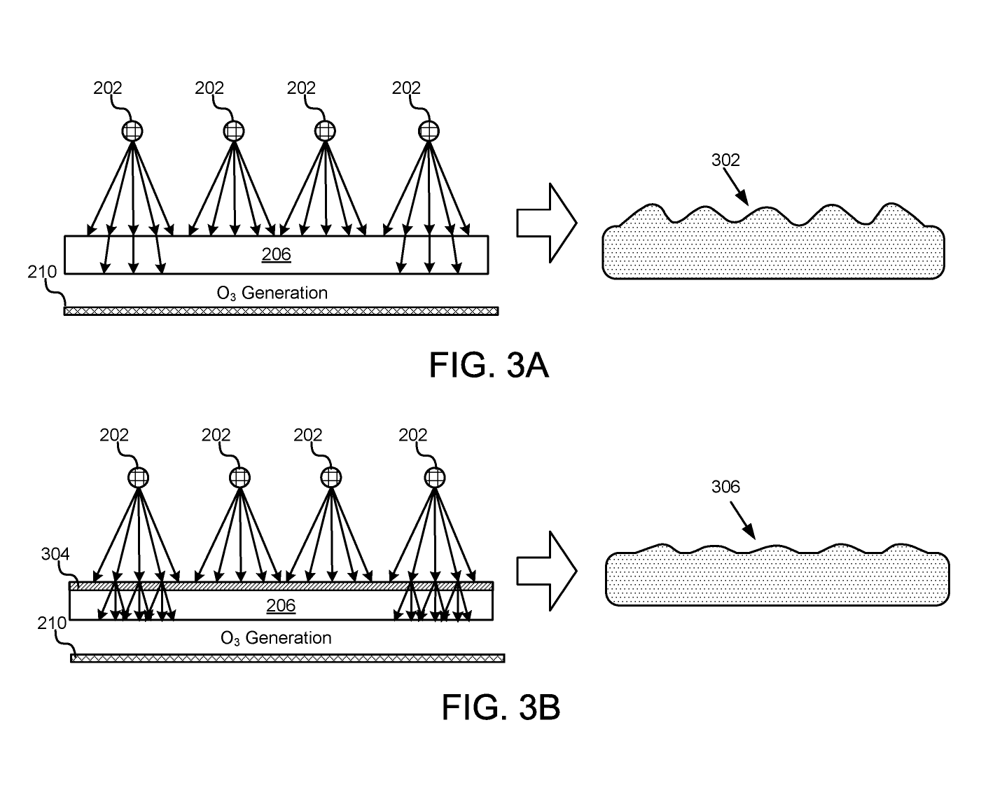

The embodiment of FIG. 3B uses a diffusive layer on a surface of the window 206 to even out the light intensity coming from the lamps 202. Whereas the embodiment of FIG. 3A does not include the diffusive layer 304, the surface 302 is less uniform than the surface 306 of the embodiment in FIG. 3B. Scattering the light with a roughened or patterned window surface brings more light to areas of the wafer that are not directly under the lamp. The window 206 can be roughened using commercially available sandblasting or polishing tools. Also, a lithography process can be used to create a pattern on the window surface to achieve close to lambertian diffusion, equivalent light intensity in every direction. A further embodiment uses the diffusive layer only in certain portions of the window that are exposed to the highest light intensity or changes the roughness across the lens to increase scattering in high intensity areas.

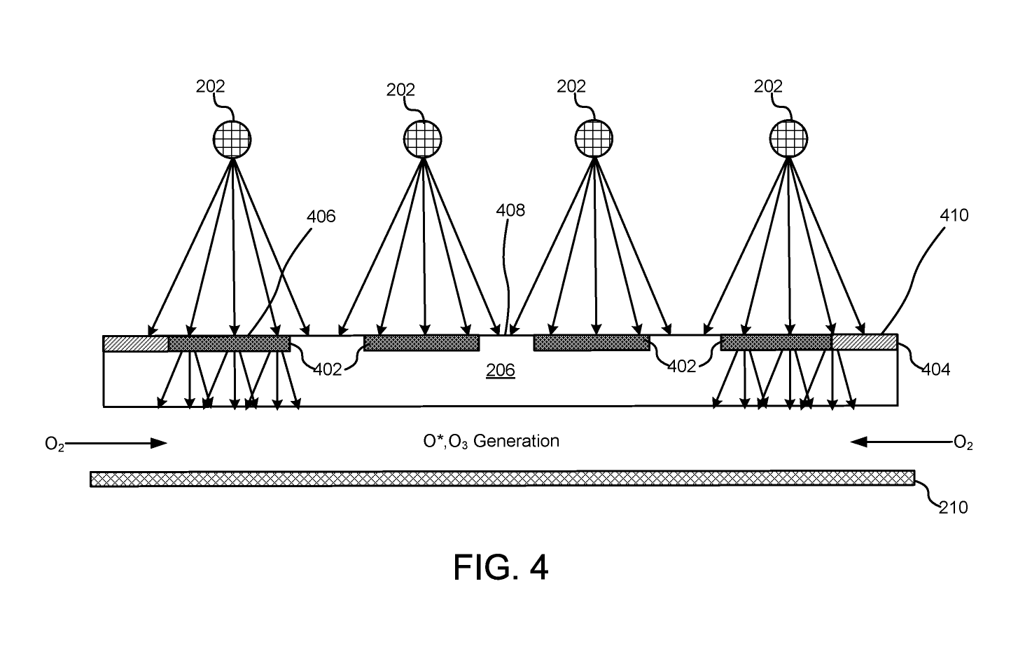

FIG. 4 illustrates an embodiment that uses a photo-interactive layer 402 or film to reduce the light intensity in the areas with the highest reaction rate. In an embodiment, the photo-interactive layer may cover the entire surface of the window 206. In other embodiments, a plurality of photo-interactive layer regions may be disposed on or in the window 206. Photo-interactive layers may be, in various embodiments, diffusive, reflective, or absorptive. In further embodiments, the photo-interactive layers may be varying degrees of diffusive, reflective, or absorptive.

In the such an embodiment, oxygen is delivered from the outside of the wafer 210, increasing the reaction rate at the wafer edge. Placing a second photo-interactive layer 404 along the edge of the window 206 and in the highest intensity areas under the lamp can even out the across wafer reaction rate. The absorbance or reflectance of this layer can gradually increase closer to the areas of highest intensity. Furthermore, the embodiments of FIGS. 3 and 4 may be combined by using the second photo-interactive layer 404 at the edge and the diffusive layer 304 in the areas of highest light intensity as shown by regions 402 in FIG. 4. This option would improve the overall removal rate versus only using an absorbing layer.

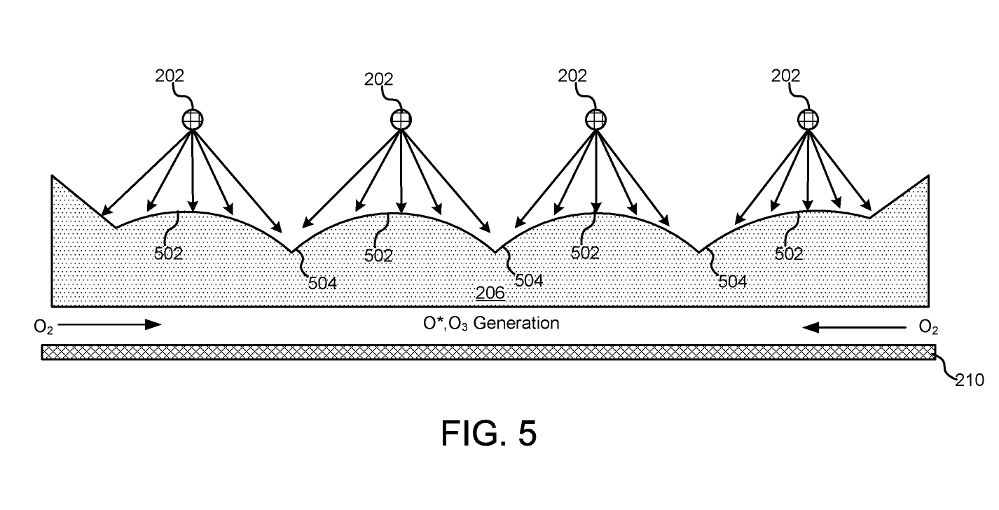

The embodiment of FIG. 5 takes advantage of the natural absorption of the fused silica window 206 to reduce variation in the SOC removal rate across wafer. Even the highest quality UV fused silica still only transmits less than 90% of light. The window thickness is increased 502 in areas with the highest measured removal rate to obtain a more planar surface. The window 206 is thinner in areas 504 of lower intensity.

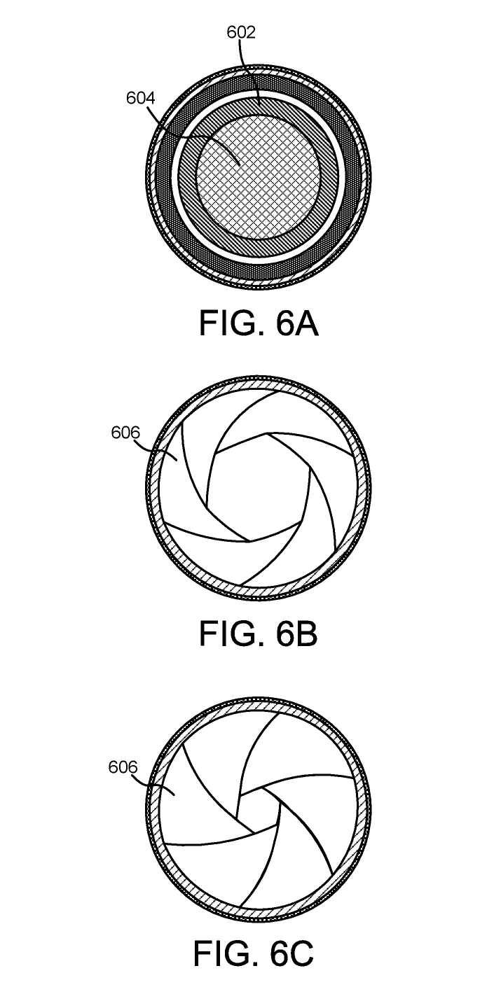

FIGS. 6A-6C illustrate an embodiment that uses a diaphragm shutter-type opening to radially control the intensity of light that is allowed to enter the window 206. The shutter-type opening forms an aperture for controllably passing light at variable intensities. In an embodiment, the light source comprises an annular bulb 602, which forms a central region of stray light 604 as shown in FIG. 6A. The diaphragm shutter 606 would maintain a circular opening while dynamically enlarging as shown in FIG. 6B. The rate of opening would be controlled to ensure each radius received as close as possible to the same amount of light during the exposure process. The annular lamp 602 may have approximately the radius of the wafer 210. Such an embodiment can ensure that the average intensity with radius is always equal by adjusting the shutter opening to keep the integrated dose constant, as shown in FIG. 6C.

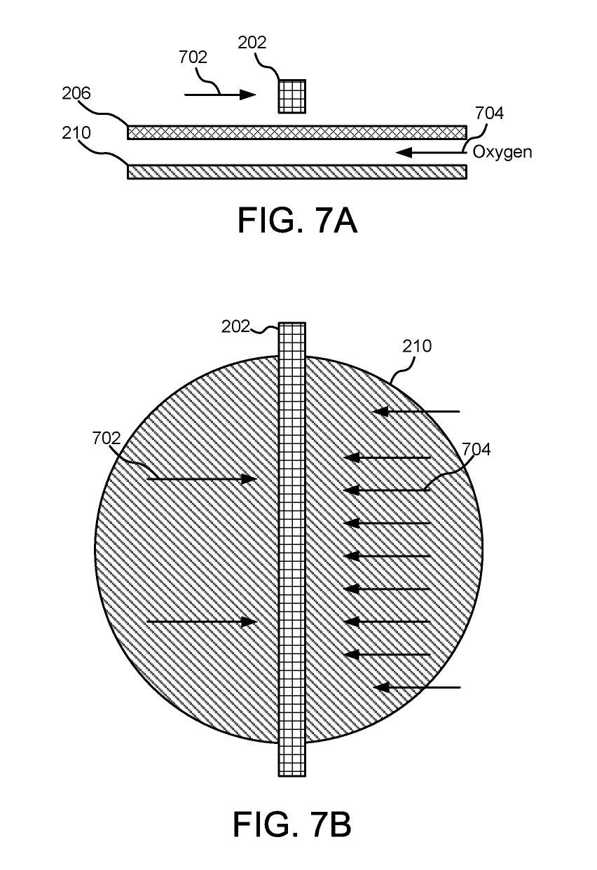

In the embodiment of FIG. 7, the substrate holder 212 rotates the wafer 210 to maintain more uniform exposure from the UV lamp 202. In such an embodiment, a ring of pins can lift and rotate the wafer 210 a preset angle after several seconds of exposure. Alternatively, the pins can be only 0.5 mm above a surface of the substrate holder 212, such that the wafer 210 can bake on the pins while slowly being rotated. This operation can be done at certain time intervals with the pins several millimeters off the surface of the substrate holder 212, or continuously with the pins 0.5 mm or less above the surface of the substrate holder. This embodiment allows uniform exposure across the wafer 210, without sacrificing the throughput benefit of multiple lamps 202.

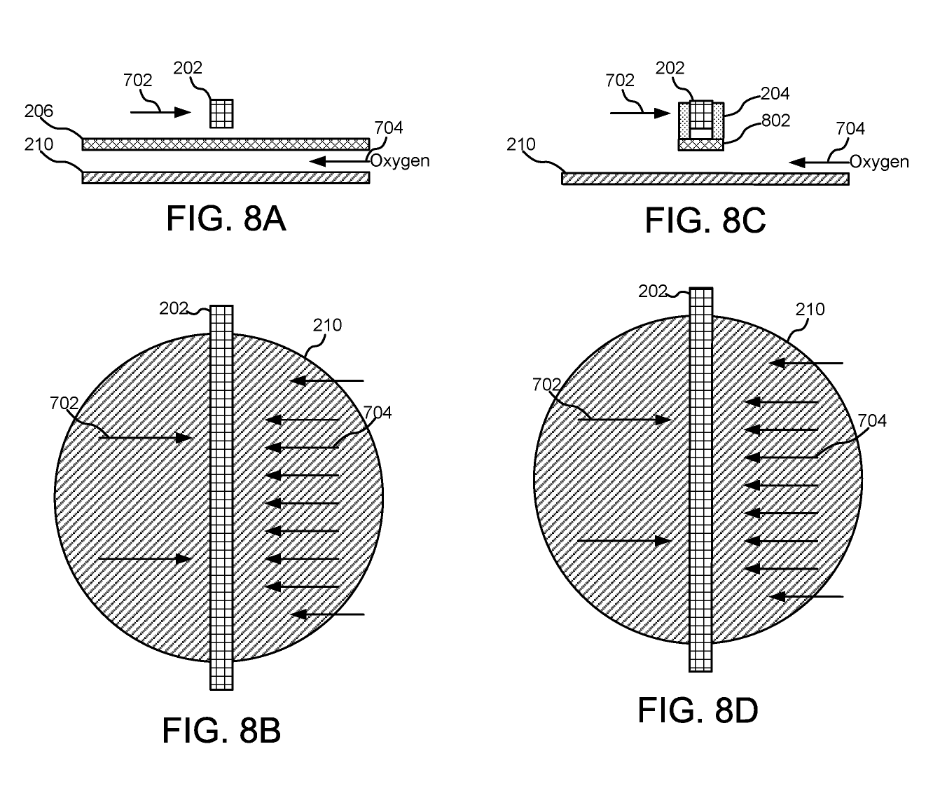

Alternatively, as shown in FIG. 7, a single lamp 202 may be used that has a length exceeding the wafer diameter. A mechanical arm or track may be used to scan the lamp 202 across the wafer 210 in a first direction 702 as shown in FIG. 8A. Oxygen or air flows in a second direction 704, that is opposite the first direction 702 to maintain a constant oxygen concentration under the lamp 202. A single gas outlet on the opposite side of the wafer may dispense the oxygen on the opposite side of the wafer 210 from where the scanning begins. Multiple gas outlets or a baffle can be used to equalize the oxygen flow rate perpendicular to the scanning lamp. Alternately the lamp 202 can remain static and the wafer 210 can scan under the lamp as in the embodiment of FIGS. 8A and 8B. Similar to the embodiment of FIG. 7, the wafer 210 can rest on pins that slide along a track. However, in this case, the track would be positioned to move the wafer 210 perpendicular to the lengthwise direction of the lamps 202. In the embodiment of FIGS. 8C-8D, the window 802 and the lamp 202 may scan together. This method reduces the size of the window 802 to be just slightly larger than the lamp 202, saving significant cost.

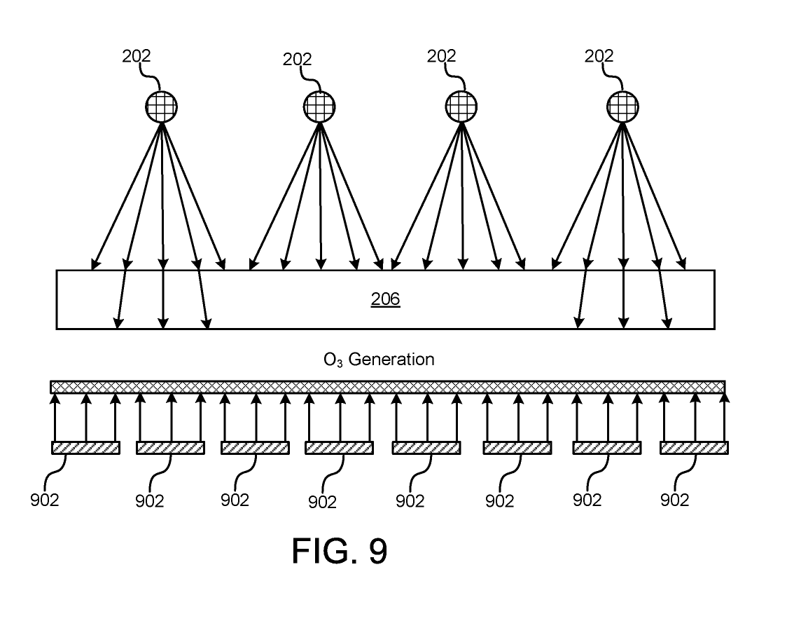

Another embodiment uses infrared heating elements 902 to control the reaction rate across the wafer 210 as shown in FIG. 9. In certain embodiments, the removal rate is temperature dependent, so inducing temperature differences across the wafer provides added process control. Energy provided by an array of heating elements 902, which may be infrared Light Emitting Diodes in some embodiments, is absorbed on the wafer backside. Due to the small thickness of the wafer 210, the temperature rises quickly through the wafer but diffuses much more slowly across the wafer. The result is that temperature gradients can be maintained during processing. The wafer 210 is suspended above the heating elements 902 using pins between the heating element panels.

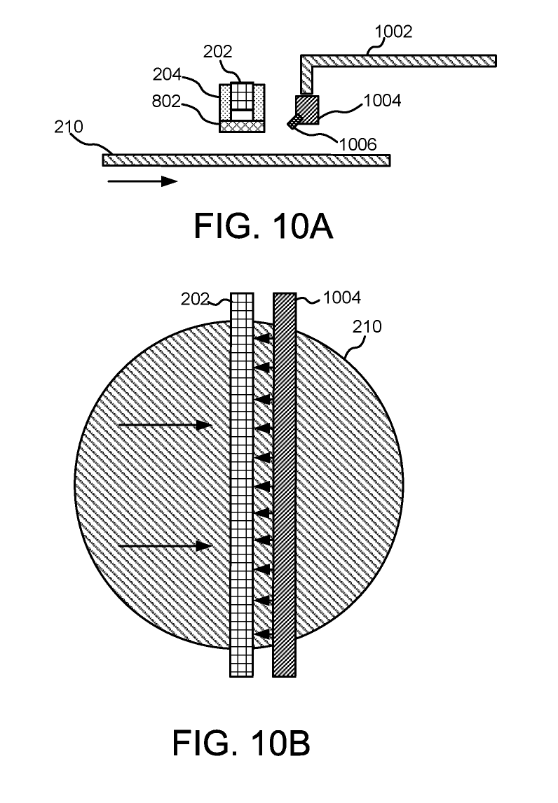

In the embodiment illustrated in FIGS. 10A-10B, a gas distribution boom or arm 1004 may be disposed at a predetermined distance from the light source 202. The gas distribution arm 1004 may be coupled to a gas inlet hose or tube 1002 for receiving the gas from an external gas source. Additionally, one or more gas outlets 1006, such as jets or nozzles, may be disposed along the gas distribution arm 1004. In such an embodiment, the gas may be injected to a gap between the light source 202 and the gas distribution arm 1004. In some embodiments, the wafer 210 may move relative to the light source 202 and gas distribution arm 1004. In alternative embodiments, the light source 202 and gas distribution arm 1004 may scan the wafer 210.

Various alternative embodiments may use small holes in the window to deliver air or oxygen gas more uniformly to the gap between the window and the wafer. A positive pressure above the window may force oxygen through the small holes into the gap. The holes are sized and placed to either evenly distribute the oxygen across the wafer or add more oxygen to areas of low light intensity to improve the uniformity of the removal rate across the wafer. This embodiment allows dual wavelength scenario wherein sub 200 nm light is used to create ozone above the window but this light is filtered by an absorbed layer on the window or just by the window material itself. 200-300 nm light still transmits through the window to break bonds within the SOC chemical. This embodiment is attractive when the SOC is placed above materials that are sensitive to sub 200 nm light such as commonly used low-k materials.

In various embodiments, a separate mechanism may be used to deliver reactive oxygen species to the wafer. A commercial ozonator, such as a corona discharge, may be used create ozone, which is then pumped into the UV exposure chamber. Piping would bring the ozone to multiple sides of the wafer. Pipes can feed into a ring with outlet ports directed toward the gap between the wafer and window. Atomic oxygen, which also has high reactivity and an acceptable half-life, can be created and pumped into the chamber or beamed directly to the wafer as explained in U.S. Pat. App. Pub. No 2014/0130825, the entire contents of which are incorporated herein by reference. A higher wavelength lamp >200 nm can be used in such embodiments, because ozone generation would no longer be required. Therefore, the light would only need to break bonds at the SOC surface.

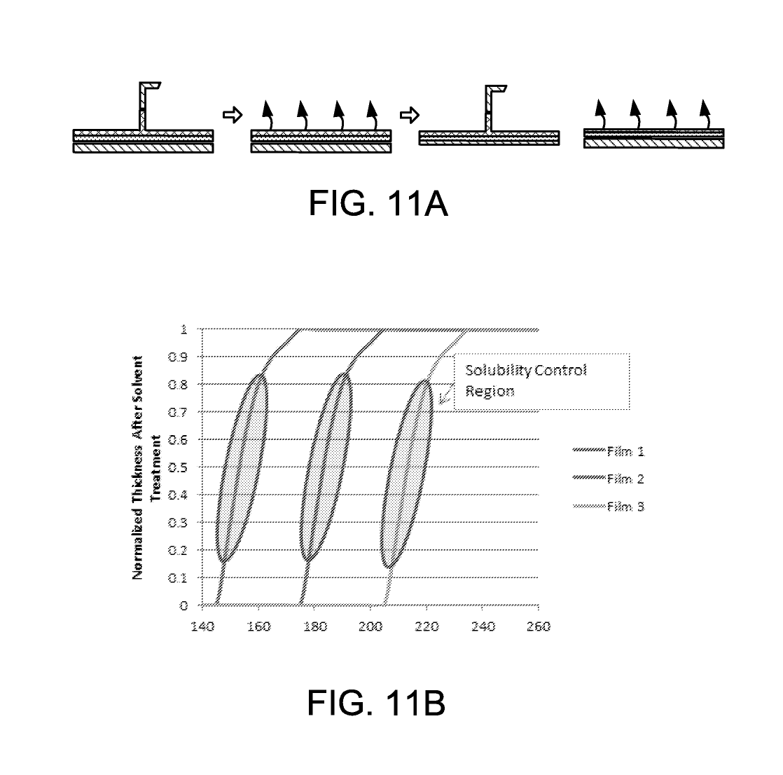

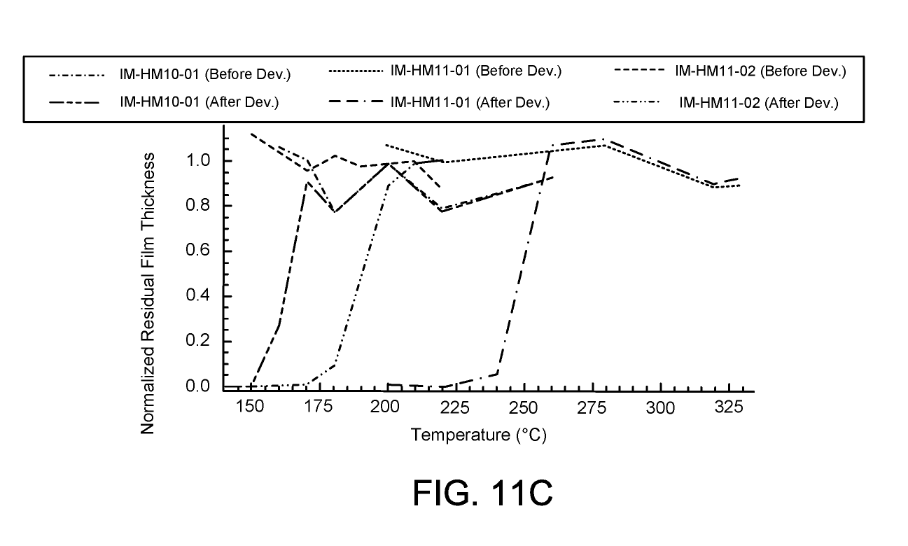

Alternative embodiments, such as those shown in FIG. 11A, may not require UV light or reactive oxygen species to planarize a spin-on material. A thicker coating of the material is still applied to planarize the surface but not baked at the high temperatures required to insolubilize the material. A low temperature bake stabilizes the coating, but maintains the solubility of the material such that a solvent rinse can be performed without completely removing the material. A solubility control region, as shown in FIG. 11B, exists for any volatile spin-on material such that baking to a temperature within this region will allow partial solubility. The amount of material removed will depend on the solvent rinse time and the diffusive boundary layer which is controlled by nozzle design, rotation speed and the volume of solvent. The solvent already being used in the RRC (reduced resist consumption) process, which helps the organic film spread on the wafer during coating, could also be used in the removal process. Alternatively, a more or less aggressive solvent might be chosen to tune the rate of removal to the desired application. In addition to a straight nozzle with a single opening as shown, rows of smaller openings can be used to improve the uniformity of the solvent/material boundary layer across the wafer.

In still further embodiments, the solvent may be used in addition to the UV radiation process, either in tandem or in sequence. The solubility of the spin-on film may be variable, depending upon the bake temperature. FIG. 11B is a shows various solubility curves as a function of temperature for some examples of organic films.

In the example of FIG. 11A, the process may include spinning on a thick organic film, such as an SOC material. The next step may include a low temperature bake, for example in a temperature range between 150° C. and 250° C. The third step may include performing a solvent rinse to partially remove the organic film and planarize the coating. The final step includes a high temperature bake to set the coating. In an embodiment, the high temperature bake may be in a temperature range between 500° C. and 700° C. One of ordinary skill in the art will recognize that various materials may be spun onto the surface of the substrate, and that various solvents may be used. The specific solvents used may depend on the chemistry of the coating, or the initial bake temperature ranges. Similarly, the first and second bake temperature ranges may depend upon the chemistry of the coating and/or the solvent to be used.

In one various, organic solvents that could be used include PGMEA (propylene glycol methyl ether acetate), PGME, Ethyl Lactate, PGME/EL blends, gamma-Butyrolactone, iso-propyl alcohol, MAK (methyl amyl ketone), MIBK (methyl iso-butyl ketone), n-butyl acetate, MIBC (methyl isobutyl carbinol), cyclohexanone, anisole, toluene, acetone, NMP (n-methyl pyrrolidone). Materials to be planarized could include (in addition to SOC): silicon-containing polymers (siloxane), spin-on metal hardmasks (include metals such as titanium, hafnium, zirconium, tin). Materials similar to photoresists in which you have a copolymer that contains both hydrophilic groups (OH terminated) and solvent soluble groups could also be planarized in this fashion, with the balance of each group (n vs 1-n below) adjusted to give the desired solubility. More hydrophilic groups will make the material less soluble. One of ordinary skill will recognize various additional organic and non-organic materials which may be used for the spin-on coating and/or the solvent.

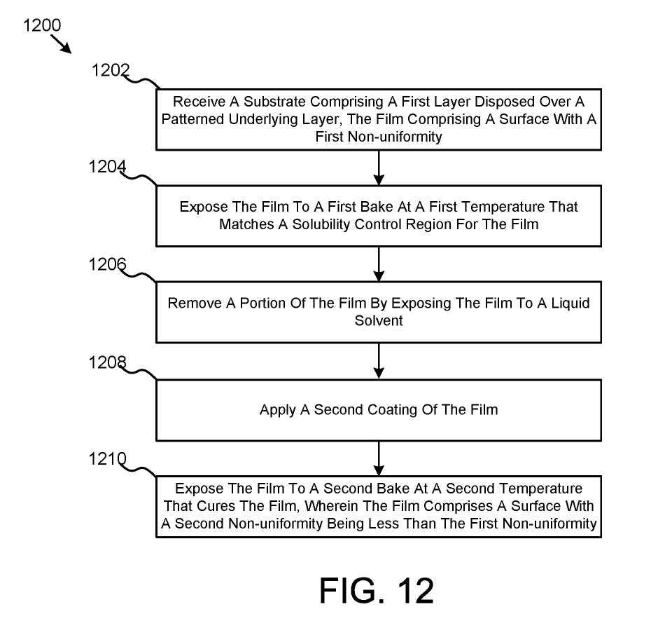

FIG. 12 illustrates one embodiment of a method 1200 for SOC planarization. In an embodiment, a method 1200 includes receiving a substrate comprising a first layer disposed over a patterned underlying layer, the film comprising a surface with a first non-uniformity, as shown at block 1202. At block 1204, the method 1200 may also include exposing the film to a first bake at a first temperature that matches a solubility control region for the film. Additionally, the method 1200 may include removing a portion of the film by exposing the film to a liquid solvent as shown at 1206. Also, the method may include applying a second coating of the film as shown at 1208. In an embodiment, the method 1200 also includes exposing the film to a second bake at a second temperature that cures the film, wherein the film comprises a surface with a second non-uniformity being less than the first non-uniformity, as shown at block 1208.

In a further embodiment, the film comprises an organic material, such as SOC, for example. In such an embodiment, the first bake may be performed in a temperature range between 150° C. and 250° C. In such an embodiment, the SOC material may still be soluble post-bake. After the solvent etch-back, the second bake may be performed at a temperature range between 500° C. and 700° C. to harden the film.

Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What we claim:

1. An apparatus, comprising:
a substrate holder configured to support a microelectronic substrate;
a light source configured to emit ultraviolet (UV) light toward a surface of the microelectronic substrate;
an isolation window disposed between the light source and the microelectronic substrate;
a gas distribution unit configured to inject gas in a region between the isolation window and the microelectronic substrate; and
an etchback leveling component configured to reduce non-uniformity of a UV light treatment of the microelectronic substrate.

2. The apparatus of claim 1, wherein the etchback leveling mechanism further comprises a photo-interactive layer disposed on at least a portion of the isolation window.

3. The apparatus of claim 2, wherein the photo-interactive layer further comprises a layer configured to interact with photo energy according to an interaction mechanism selected from the group consisting of diffusion, reflection, and absorption.

4. The apparatus of claim 2, wherein the etchback leveling mechanism further comprises a first plurality of photo-interactive regions disposed on the isolation window and a second plurality of photo-interactive regions disposed on the isolation window, the second plurality of photo-interactive regions comprising at least one optical characteristic that is different from the first plurality.

5. The apparatus of claim 1, wherein the isolation window comprises one or more first regions having a thickness that is greater than one or more second regions.

6. The apparatus of claim 1, wherein the etchback leveling mechanism further comprises an aperture device disposed between the light source and the microelectronic substrate.

7. The apparatus of claim 1, wherein the etchback leveling mechanism is configured to move the microelectronic substrate relative to the light source.

8. The apparatus of claim 7, wherein the etchback leveling mechanism is configured to rotate the microelectronic substrate about an axis.

9. The apparatus of claim 7, wherein the etchback leveling mechanism is configured to slide the microelectronic substrate along a plane that is parallel to a plane in which the light source is disposed.

10. The apparatus of claim 1, wherein the etchback leveling mechanism is configured to move the light source relative to the surface of the microelectronic substrate.

11. The apparatus of claim 10, wherein the isolation window is coupled to the light source, and configured to move with the light source relative to the microelectronic substrate.

12. The apparatus of claim 1, wherein the gas distribution unit is configured to generate etchant components external to the region between the window and the microelectronic substrate.

13. The apparatus of claim 1, wherein the gas distribution unit comprises:
a gas distribution nozzle disposed adjacent and parallel to the light source, the gas nozzle comprising:
a nozzle length that extends along at least a portion of the light source; and
a plurality of gas outlets distributed along the nozzle length.

14. The apparatus of claim 13, wherein the gas distribution unit is configured to move in tandem with the light source.

15. The apparatus of claim 1, wherein the substrate holder further comprises a plurality of heating elements, the heating elements configured to dynamically control a heating profile applied to the microelectronic substrate.

16. A method, comprising:
receiving a substrate comprising a first layer disposed over a patterned underlying layer, the film comprising a surface with a first non-uniformity;
exposing the film to a first bake at a first temperature that matches a solubility control region for the film;
removing a portion of the film by exposing the film to a liquid solvent;
applying a second coating of the film; and
exposing the film to a second bake at a second temperature that cures the film, wherein the film comprises a surface with a second non-uniformity being less than the first non-uniformity.

17. The method of claim 16, wherein the film comprises an organic material.

18. The method of claim 17, wherein the organic material comprises spin-on-carbon (SOC).

19. The method of claim 16, where the first temperature is in a range between 150° C. and 250° C.

20. The method of claim 16, wherein the second temperature is in a range between 500° C. and 700° C.
